(19) United States
(12) Patent Application Publication
(10) Pub. No.: US 2018/0124951 A1
(43) Pub. Date: May 3, 2018

(54) WATER WALL

(71) Applicant: HEWLETT PACKARD ENTERPRISE DEVELOPMENT LP, Houston, TX (US)

(72) Inventors: David A. Moore, Tomball, TX (US); John Franz, Houston, TX (US); Guillermo A. Gomez, Houston, TX (US)

(21) Appl. No.: 15/568,067

(22) PCT Filed: May 29, 2015
(86) PCT No.: PCT/US2015/033382

§ 371 Date: Oct. 20, 2017

(51) Int. Cl. H05K 7/20

(52) U.S. Cl. CPC H05K 7/20272; H05K 7/20781; H05K 7/20281

(57) ABSTRACT

A water wall is provided herein. An example water wall includes a top member, a thermal member, an orifice member, and a manifold member. The top member to expose a portion of a thermal module. The thermal member to position and hold the thermal module in the water wall. The orifice member to provide a supply passage and a return passage to the thermal module. The, manifold member to distribute fluid across the water wall.

### BACKGROUND

Electronic devices have temperature requirements Heat from the use of the electronic devices is controlled using cooling systems. Examples of cooling systems include air and liquid cooling.

### BRIEF DESCRIPTION OF THE DRAWINGS

Non-limiting examples of the present disclosure are described in the following description, read with reference to the figures attached hereto and do not limit the scope of the claims. In the figures, identical and similar structures, elements or parts thereof that appear in more than one figure are generally labeled with the same or similar references in the figures in which they appear. Dimensions of components and features illustrated in the figures are chosen primarily for convenience and clarity of presentation and are not necessarily to scale. Referring to the attached figures:

FIG. 1 illustrates a block diagram of a water wall according to an example;

FIGS. 2-6 illustrate portions of the water water wall of FIG. 1 according to examples;

FIG. 7 illustrates a block diagram of a system according to an example.

FIG. 8 illustrates an exploded view of a portion of the system of FIG. 7 according to an example;

FIG. 9 illustrates a anal view of portion of the system of FIG. 7 according to an example;

FIG. 10 illustrates a schematic diagram of a portion of the system of FIG. 7 according to an example; and

FIG. 11 illustrates a flow chart of a method to distribute fluid across a water wall according to an example.

### DETAILED DESCRIPTION

In the following detailed description, reference is made to the accompanying drawings which form a part hereof, and in which is depicted by way of illustration specific examples in which the present disclosure may be practiced. It is to be understood that other examples may be utilized and structural or logical changes may he made without departing from the scope of the present disclosure.

The liquid cooling solutions that exist for server equipment typically include fluid connections between a server and a cooling device positioned at either the front or rear of the server. For example, the connection may be formed by manual connection of tubes or a blind mate system. A thermal connection used for a dry disconnect liquid cooling system may be made by providing a liquid cooled surface to accept heat by conduction from an adjacent surface, such as on a side of the server. A connection in a dry disconnect liquid cooling system works efficiently when the server and a cooling device are properly aligned. When the connection between the server and cooling device is not properly aligned the heat may not transfer efficiently. Moreover, the server or cooling device may be damaged when the two are not properly aligned.

The phrase “electronic module” as used herein refers to a computing device, such as a power supply, a network switch, a server, a blade server, or a server cartridge that provides computer solutions, storage solutions, network solutions, and/or cloud services.

The phrase “thermal module” as used herein refers to any mechanism to cool or remove heat from the electronic module. The thermal module may also be referred to as a cooling module. A thermal bus bar that collects heat from the electronic module and removes the heat from a server rack is an example of a thermal or cooling module.

The phrase “dry disconnect” as used herein refers to a module assembly with cooling components that cool an electronic module using a liquid cooling method. The liquid cooling method uses a fluid manifold to direct a cooling fluid and a thermal mating member or surface that mates with the electronic module. For example, the thermal mating member may mate with a condenser plate or a heat block formed of a thermally conductive material to receive heat from the electronic module.

The phrase “water wall” as used herein refers to a structure formed to distribute the liquid to a fluid manifold in a dry disconnect coding system. The water wall is typically connected to the rack adjacent to the electronic module.

In examples, a water wall is provided. The water wall includes a top member, a thermal member, an orifice member, a manifold member, and a back member. The top member to expose a portion of a thermal module. The thermal member to position and hold the thermal module in the water wall. The orifice member to provide a supply passage and a return passage to the thermal module. The manifold member to distribute fluid across the water wall. Fluid is reliably distributed across the manifold member with the pressure and supply balanced during distribution.

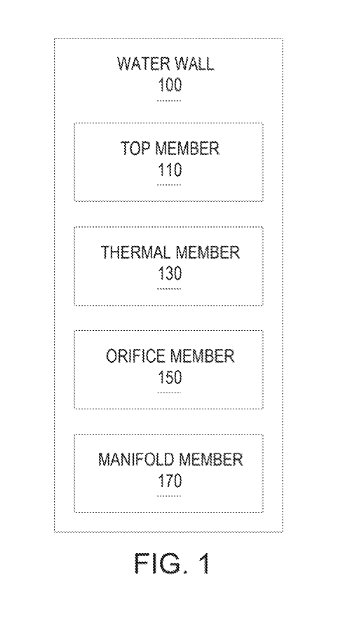

FIG. 1 illustrates a block diagram of a water wall 100 according to are example. The water wall 100 includes a top member 110, a thermal member 130, an orifice member 150, and a manifold member 170. The top member 110 including an aperture to expose a portion of a thermal module. The thermal member 130 to position and hold the thermal module in the water wall. The orifice member 150 to provide a supply passage and a return passage to the thermal module. The manifold member 170 to distribute fluid across the water wall 100.

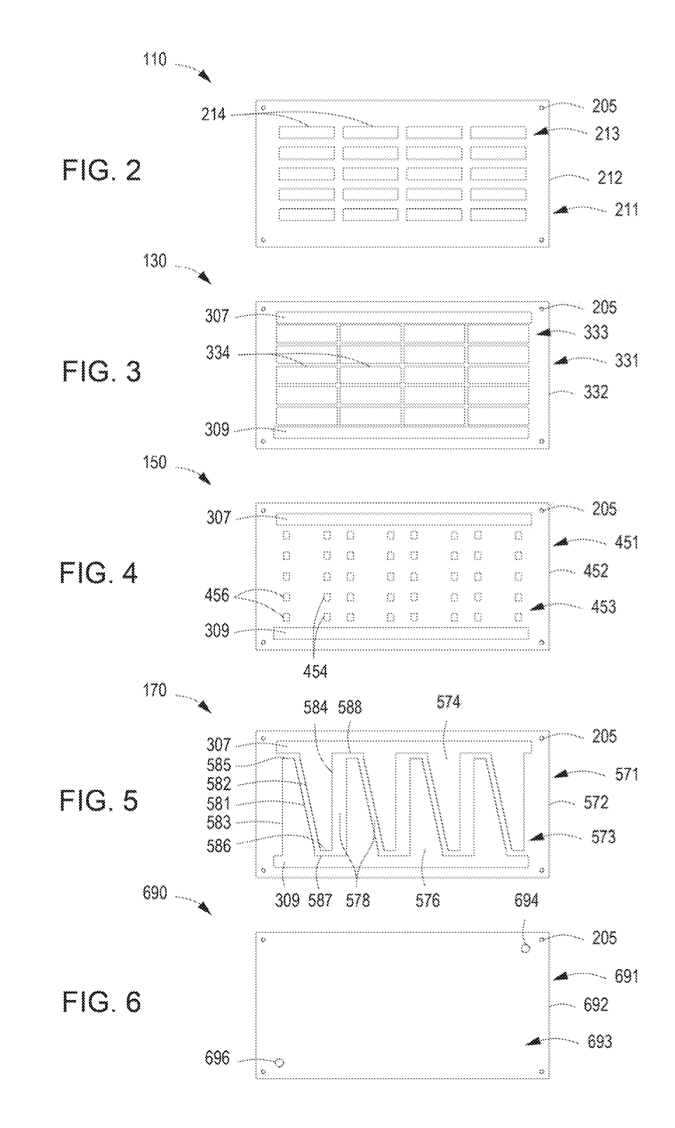

FIGS. 2-6 illustrate portions of the water wall 100 of FIG. 1 according to examples. The water wall 100 may be connected via adhesive, stitching, and/or fasteners. The water wall 100 may be positioned and retained within an electronic system using fasteners, such as screws, via fastening apertures 205. Referring to FIG. 2, the top member 110 is illustrated to expose the thermal module so that the thermal module can receive heat from servers, electronic components, or modules designed to mate with the thermal module. For example, the thermal module may include a pin fin array that may function as a heat exchanger. The top member 110 also includes an outer seal around a perimeter of the top member 110. For example, the top member 110 may include a top perimeter 212 that forms the outer edges of the top member 110 and forms the outer seal. The top perimeter 212 aligns the top member 110 with an electronic module on one side 211 and the thermal member 130 on the opposite side 213. The top member 110 also includes thermal slots or apertures 214 that expose a portion of the thermal module. The thermal slots 214 may form a module seal around the thermal module.

FIG. 3 illustrates the thermal member 130. The thermal member 130 includes a thermal perimeter 332 with frames 334 formed therein that position and hold the thermal module in the water wail 100. The thermal perimeter 332 aligns the thermal member 130 with the top member 110 on one side 331 and the orifice member 150 on the opposite side 333. The thermal member 130 also includes a supply channel 307 and a return channel 309. The supply channel 307 and return channel 309 are illustrated on opposite ends of the thermal member 130 and span the length of the thermal member 130. The supply and return channels 307, 309 are illustrated with a depth through three layers, the thermal member 130, orifice member 150, and manifold member 170. The depth of the supply and return channels 307, 309 may vary and the depth may change along the length of the thermal member 130 to control fluid flow. For example, a first portion of the supply and return channels 307, 309 may be three layers, a second portion of the supply and return channels 307, 309 may be two layers, and a third portion of the supply and return channels 307, 309 may be one layer. The size of each of the first, second and third portions may or may not be equal.

The orifice member 150 as illustrated in FIG. 4 includes an orifice perimeter 452 that mates with the thermal member 130 on one side 451 and the manifold member 170 on the opposite side 453. The orifice member 150 includes supply and return channels 307, 309 at opposite ends. The orifice member 150 also includes a supply passage 454 and a return passage 456. The supply passage 454 and return passage 456 each include a fluid aperture aligned with the thermal module, such that the supply passage 454 provides fluid to the thermal module and the return passage 456 receives fluid from the thermal module. For example, the supply and return passages 454, 456 may be distributed across the orifice member 150 such that there is a supply passage 454 and a return passage 456 aligned with each thermal module. The supply passage 454 does not directly receive fluid from the supply channel 307, and the return passage 456 does not directly provide fluid to the return channel 309, instead the manifold member 170 controls the flow of fluid.

The manifold member 170 is illustrated in FIG. 5. A manifold perimeter 572 mates the manifold member 570 with the orifice member 150 on one side 571 and the back member 690 on the opposite side 573. The manifold member includes the supply channel 307 and the return channel 309. The supply channel 307 and the return channel 309 include branches that span the manifold member 170, such as a supply branch 574 and a return branch 576. The supply channel 307 to distribute fluid to the thermal module via a supply branch 574. The return channel 309 to receive fluid from the thermal module via a return branch 576. The supply branch 574 and the return branch 576 include at least one feature to control flow and balance pressure of fluid. For example, the supply branch 574 and the return branch 576 are both tapered as they provide fluid to the thermal modules via the supply and return passages 454, 456 at the orifice member 150.

FIG. 5 illustrates the supply branch 574 and the return branch 576 having complementary patterns that transport fluid in a similar pattern across the water wall. For example, the supply branch 574 and the return branch 576 may be tapered and may have rotational symmetry. The tapered design includes angled walls 581. 582, straight walls 583, 584, and connecting walls 585-588. The walls 581-588 may include one or more straight, angled, or connecting sections to form the walls of the supply branch 574 and the return branch 576.

The supply branch 574 and return branch 576 may have additional features that enhance flow balance. For instance, the walls may taper in steps, curves, or a combination of both. The open region of the branches may have partial blockages extending from the walls or forming “island” areas. The intent of such features is to further balance flow across the multiple passages, and under a range of flow conditions. The symmetry of the tapered sections balance the flow of fluid and provides fluid to and receives fluid from the thermal modules in a controlled manner. The supply branch 574 and the return branch 576 span the manifold member lengthwise to provide additional cross sectional area, which reduces pressure drop and helps balance the flow of fluid.

The water wall 100 may further include a back member 690 as illustrated in FIG. 6. The back member 690 may include a bottom planar surface 692 that aligns with the manifold member 170 on one side 691 and optionally aligns with an exoskeleton on the opposite side 693. The planar surface 692 may be flexible or rigid. For example, the back member 690 may be rubber, such as neoprene rubber, like the other members of the water wail 100. Alternatively, the back member may be a rigid layer forming a structural support or attachment for the water wall 100, for example, attachment to a rack structure. When the back member 690 is rubber, an additional exoskeleton or support may be connected to the back member 690 as a unitary member or separate member connected to the opposite side 693 of the bottom planar surface 692. The additional exoskeleton may be similar to the back member 690 in shape, size, and features, but it would be formed of a rigid material to support the water wall 100.

Supply and return apertures 694, 696 may house fittings to provision fluid supply and return. Supply and return apertures 694, 696 may be connected to the back member 690. The supply aperture 694 to provide fluid to the water wall 100. The return aperture 696 to remove fluid from the water wall 100. The supply and return aperture 694, 696 connected to the supply channel 307 and the return channel 309 described above. The supply and return apertures 694, 696 may be fitted with valves, blind mate connectors, barbed fittings, or other fluid connections in order to connect fluid supply and return channels 307, 309. The supply and return apertures 694, 696 may be connected to the back of the back member 690 or through apertures in the side of the water wall 100 along the supply and return channels 307, 309.

The top member 110, thermal member 130, orifice member 150, manifold member 170, and/or back member 690 may be adhesively layered and reinforced with fibers, stitching, screws and/or fasteners to add strength. One or more of the members 110, 130, 150, 170, and 690 may be flexible which may reduce contact pressure required to mate the thermal module. Molded inserts in the top member 110 and/or thermal member 130 may hold the thermal module in place. Moreover, the water wall 100 may be two-sided, such that a thermal module may be positioned on two opposing sides of the water wall 100. For example, the layers may include a top member 110, a thermal member 130, an orifice member 150, a manifold member 170, a back member 690 a manifold member 170, an orifice member 150, a thermal member 130, and a top member 110. Alternatively, the layers may include a top member 110, a thermal member 130, an orifice member 150, a manifold member 170, an orifice member 150, a thermal member 130, and a top member 110. In yet a further example, the layers may include a first water wall 100 including a top member 110, a thermal member 130, an orifice member 150, a manifold member 170, a back member 690 adjacent to a second water wall 100 including a back member 690, a manifold member 170, an orifice member 150, a thermal member 130, and a top member 110. In various arrangements, the top member 110 and/or the back member 690 may contain fluid within the water wall 100.

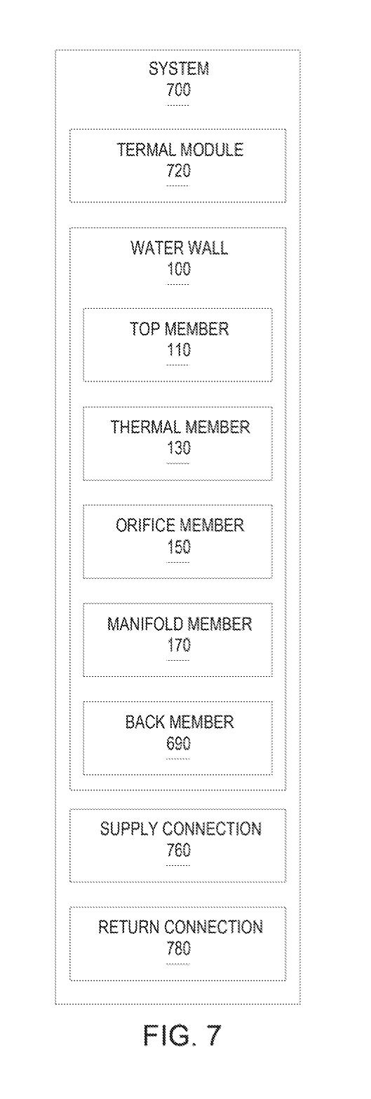

FIG. 7 illustrates a block diagram of a system 700 according to an example. The system 700 includes a thermal module 720, a water wall 100, a supply connection 760 to provide fluid to the water wall 100, and a return connection 780 to receive fluid from the water wall 100. The water wall 100 includes a top member 110, a thermal member 130, an orifice member 150, a manifold member 170, and a hack member 690.

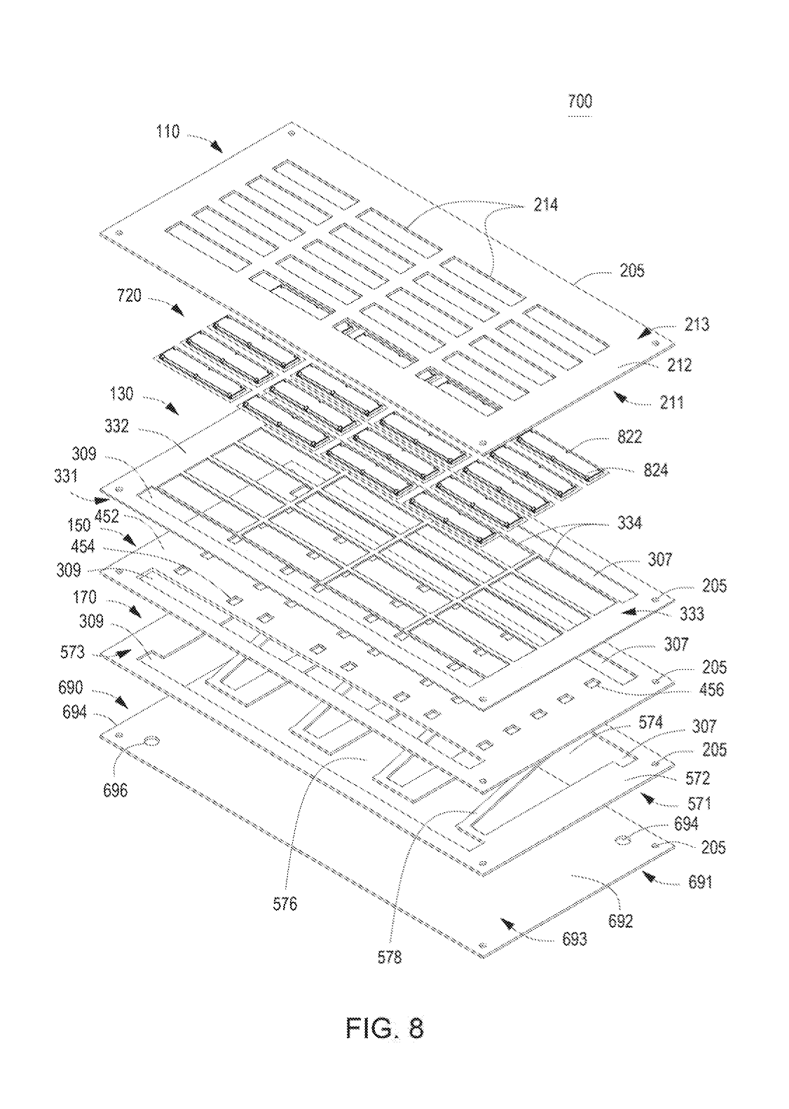

FIG. 8 illustrates an exploded view of a portion of the system 700 of FIG. 7 according to an example. Referring to FIG. 8, the thermal module 720 and the water wall 100 are illustrated. The system 700 illustrated in FIG. 8 may cool twenty central processing units (CPUs) or general purpose graphical processing units (GP-GPUs) vertically mounted in the center of a rack when thermal modules 720 are coupled to the water wall 100. Thermal modules 720 to remove heat from electronic modules, such as CPUs or GPUs. The thermal module 720 includes a planar thermal layer 822 with pin fin arrays 824 made of a thermally conductive material disposed to receive waste heat from adjacent electronic components.

The water wall 100 includes the top member 110, the thermal member 130, the orifice member 150, the manifold member 170, and the back member 690. The top member 110 is to receive the thermal modules 720 and mate a portion of each thermal module 720 with an electronic module. The top member 110 to provide a first seal of the water wall 100. The thermal member 130 to maintain the thermal module 720 in the water wall 100. The orifice member 150 to provide a pair of passages to each thermal module 720. The pair of passages to provide fluid to the thermal module and remove fluid from the thermal module 720. The manifold member 170 to uniformly distribute fluid across the water wall 100. The back member 690 to provide a fluid-tight seal from fluid within the water wall 100. The back member 690 positioned on a side of the water wall 100 opposite the top member 110 to provide a second seal for the water wall 100.

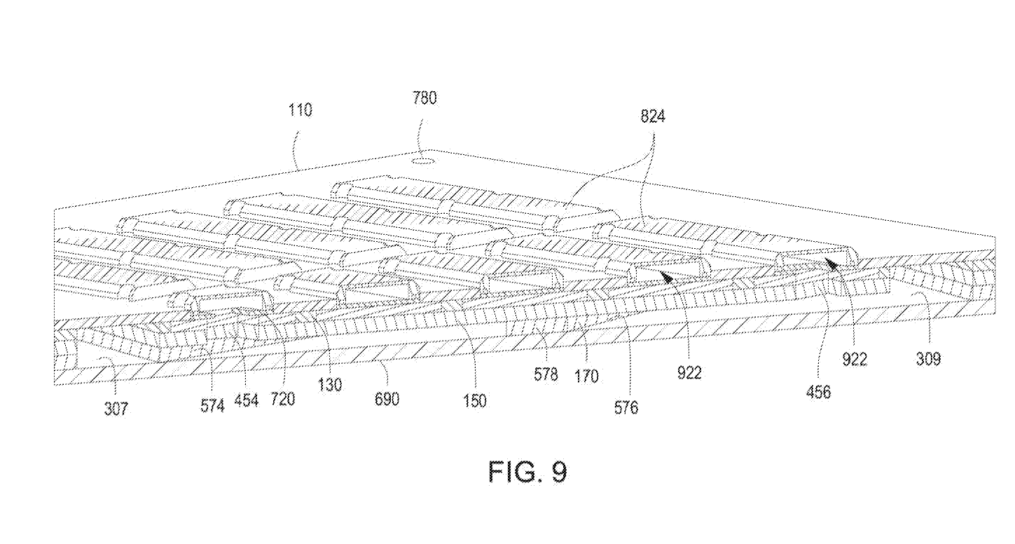

FIG. 9 illustrates a cross-sectional view of a portion of the system 700 of FIG. 7 according to an example. In FIG. 9, the top member 110, thermal member 130, orifice member 150, manifold member 170, and back member 690 are assembled together to provide a fluid-tight seal. The thermal modules 720 are between the top member 110 and the thermal member 130 such that the thermal member 130 surrounds each thermal module 720. The system 700 provides even flow distribution through the members or layers. The flow starts at the supply connection 760 and spreads along the supply channel 307. Fluid flows up through the orifice member 150 and across the thermal modules 720 then down through the orifice member 150, across the return channel 309, and out through the return connection 780.

As illustrated in the cross-section of FIG. 9, the supply channel 307 is three layers in depth, which provides a greater cross sectional area for flow of fluid. The supply branch 574 is tapered. The supply branch 574 supplies fluid up through the orifice member 150 (via the supply passage 454) and into the thermal module 720, such as a set of pin fin arrays 824 that function as a heat exchanger. A divider 578 is illustrated between the supply branch 574 and the return branch 576 to separate the supply branch 574 and the return branch 576. The top member 110, thermal member 130, and orifice member 150 trap or hold the thermal module into place and provide a seal. Fluid may flow from a cavity 922 formed in the pin fin arrays 824 of thermal module 720 back down through the orifice member 150 (via the return passages 456) and into the return branch 576 of the manifold member 170. Fluid then flows into the three layer return channel 309, as described above in FIG. 3.

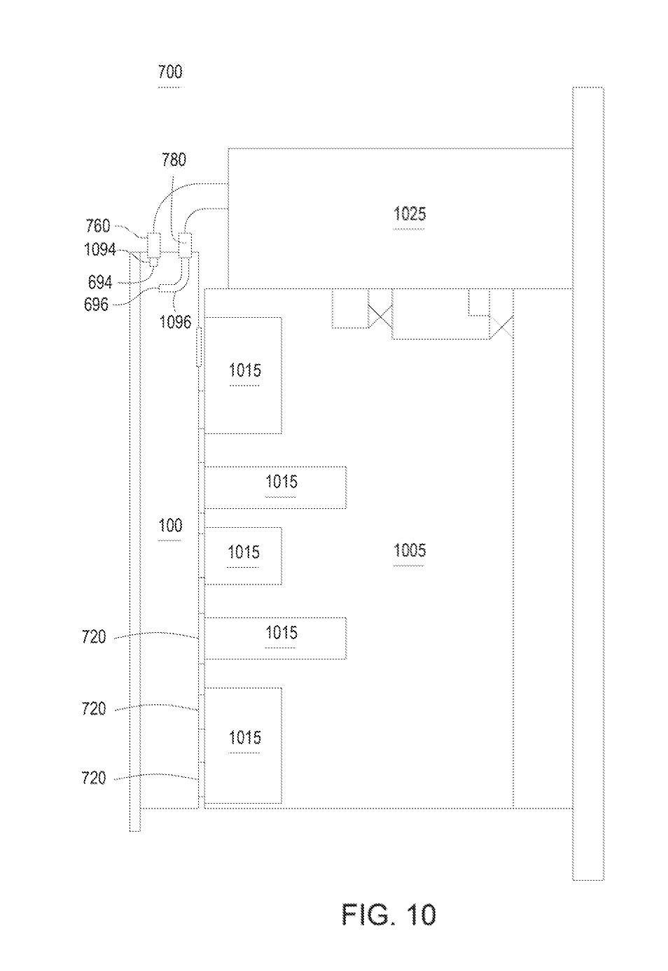

FIG. 10 illustrates a schematic diagram of a portion of the system 700 of FIG. 7 according to an example. In FIG. 10, the water wall 100 is positioned adjacent to an electronic module 1005. The thermal modules 720 extend from the water wall 100 and mate with electronic components 1015, such as a heat sink, condenser plate, or heat block of the electronic module 1005. The water wall 100 receives fluid via the supply connection 760 that is connected to a supply aperture 694. The supply connection 760 is connected to a coolant distribution unit 1025. Fluid is removed from the water wall 100 via the return connection 780 connected to a return aperture 896. The return connection 780 is connected to the coolant distribution unit 1025. The supply connection 760 and the return connection 780 may include fittings 1094, 1096 for fluid supply and return.

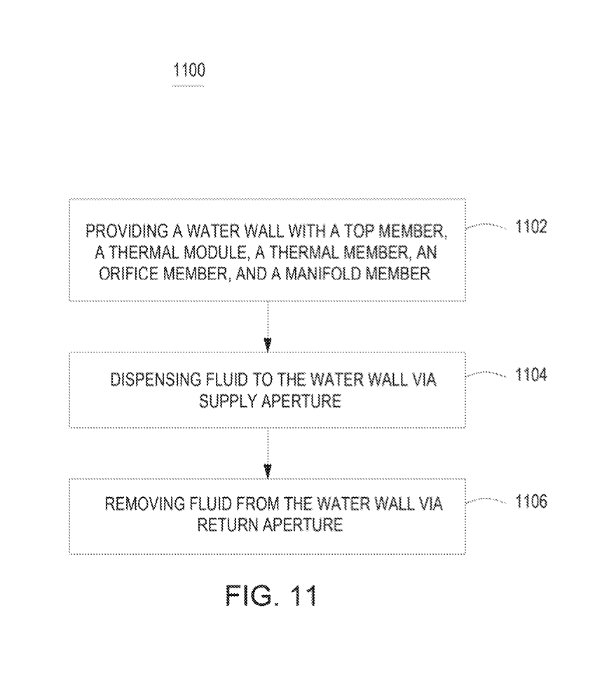

FIG. 11 illustrates a flow chart 1100 of a method to distribute fluid across a water wall according to an example. Block 1102 provides a water wall. The water wall includes a top member, a thermal member, an orifice member, a manifold member, and a back member. The top member to receive the thermal module and mate a portion of the thermal module with an electronic module. The thermal module to remove heat from the electronic module. The top member to provide a first fluid-tight seal on a first side of the water wall facing an electronic module. The thermal member to retain the thermal module in the water wall. The orifice member to provide fluid to the thermal module and remove fluid from the thermal module. The manifold member to distribute fluid across the water wall in a pattern traversing the manifold member in regular pattern. The back member is positioned on a side of the water wall opposite the top member to provide a second fluid-fight seal for the water wall.

Referring to block 1104, fluid is dispensed to the water all via a supply aperture connected to a supply connection on the water wall. In block 1106 fluid is removed from the water wall via a return aperture connected to a return connection on the water wall.

As illustrated above, the top member, the thermal member, the orifice member, the manifold member, and the back member may be separate components. For example, each member may be formed of rubber, such as neoprene rubber, that is punched out or cut out using a water-jet cutter. Each member may form a distinct layer and be fabricated as a distinct layer, which simplifies manufacturing by enabling each layer or piece to be cut independent of the other pieces.

Moreover, the thickness of each layer may be uniform or vary, depending on the specifications for the desired use. Furthermore, the layers may be adapted to be two-sided by joining two assemblies together or forming a water wall that includes two manifold members 170, two orifice members 150, two thermal members 130, and two top members 110 as described above with respect to FIGS. 2-6.

Although the flow diagram 1100 of FIGS. 11 illustrate specific orders of execution, the order of execution may differ from that which is illustrated. For example, the order of execution of the blocks may be rearranged relative to the order shown. Also, the blocks shown in succession may be executed concurrently or with partial concurrence. All such variations are within the scope of the present invention.

The present disclosure has been described using non-limiting detailed descriptions of examples thereof and is not intended to limit the scope of the present disclosure. It should be understood that features and/or operations described with respect to one example may be used, with other examples and that not all examples of the present disclosure have all of the features and/or operations illustrated in a particular figure or described with respect to one of the examples. Variations of examples described will occur to persons of the art. Furthermore, the terms “comprise,” “include,” “have” and their conjugates, shall mean, when used to the present disclosure and/or claims, “including but not necessarily limited to.”

It is noted that some of the above described examples may include structure, acts or details of structures and acts that may not be essential to the present disclosure and are intended to be exemplary. Structure and acts described herein are replaceable by equivalents, which perform the same function, even if the structure or acts are different, as known in the art. Therefore, the scope of the present disclosure is limited only by the elements and limitations as used in the claims.

What is claimed is:

1. A water wall comprising:
a top member including an aperture to expose a portion of a thermal module:
a thermal member to position and hold the thermal module in the water wall;
an orifice member to provide a supply passage and a return passage to the thermal module; and
a manifold member to distribute fluid across the water wall.

2. The water wall of claim 1, wherein the top member comprises an outer seal around a perimeter of the top member.

3. The water wall of claim 1, wherein the top member comprises a module seal around the thermal module.

4. The water wall of claim 1, wherein the supply passage and return passage each comprise a fluid aperture aligned with the thermal module.

5. The water wall of claim 4, wherein the manifold member comprises:
a supply channel to distribute fluid to the thermal module via a supply branch section, and
a return channel to receive id from the thermal module via a return branch section.

6. The water wall of claim 5, wherein the supply branch section and the return branch section comprise at least one feature is control flow and balance pressure fluid.

7. The water wall of claim 5, wherein the supply branch and the return branch comprise complementary patterns that transport fluid across the water wall.

8. The water wall of claim 5, wherein the water wall further comprises a back member to provide a fluid-tight seal id within the water wall.

9. A system comprising:
a thermal module coupled to a water wall to remove heat from an electronic module;
the water wall including:
a top member to receive the thermal module and mate a portion of the thermal module with an electronic module, the top member to provide a first seal of the water wall,
a thermal member to maintain the thermal module in the water wall,
an orifice member to provide a pair of passages to the thermal module, the pair of passages to provide fluid to the thermal module and remove fluid from the thermal module,
a manifold member to uniformly distribute fluid across the water wall, and
a back member positioned on a side of the water wall opposite the top member to provide a second seal for the water wall;
a supply connection to provide fluid to the water wall; and
a return connection to receive fluid from the water wall.

10. The system of claim 9, wherein the supply connection comprises a supply aperture.

11. The system of claim 9, wherein the return connection comprises a return aperture.

12. The system of claim 9, wherein the thermal member surrounds the thermal module.

13. The system of claim 9, wherein the thermal module comprises a pin fin array made of a thermally conductive material disposed to receive waste heat from adjacent electronic components.

14. A method to distribute fluid across s water wall, the method comprising:
providing a water wall, the water wall includes:
a top member to receive the thermal module and mate a portion of the thermal module with an electronic module, the top member to provide a first fluid-tight seal on a first side of the water wall facing an electronic module,
a thermal member to retain the thermal module in the water wall,
an orifice member to provide fluid to the thermal module and remove fluid from the thermal module,
a manifold member to distribute fluid across the water wall in a pattern traversing the manifold member in regular pattern, and
a back member positioned on a side of the water wall opposite the top member to provide a second fluid-tight seal for the water wall:
dispensing fluid to the water wall via a supply aperture connected to a supply connection on the water wall; and
removing fluid from the water wall via a return aperture connected to a return connection on the water wall.

15. The method claim 14, further comprising providing the top member, the thermal member, the orifice member, the manifold member, and the back member as separate components.
